(19) United States
(12) Patent Application Publication
(10) Pub. No.: US 2017/0365574 A1
(43) Pub. Date: Dec. 21, 2017

(54) MICROWAVE CONNECTORS FOR SEMICONDUCTOR WAFERS

(71) Applicant: International Business Machines Corporation, Armonk, NY (US)

(72) Inventors: David W. Abraham, Croton, NY (US); John M. Cotte, New Fairfield, CT (US)

(21) Appl. No.: 15/184,187

(22) Filed: Jun. 16, 2016

(51) Int. Cl. H01L 23/00; H01L 21/48; H01L 23/498; H01L 23/66

(52) U.S. Cl. CPC H01L 24/29; H01L 23/66; H01L 24/83; H01L 21/4853; H01L 23/49838; H01L 2224/83815

(57) ABSTRACT

Embodiments are directed to a coupler system including a semiconductor wafer, an interconnect layer formed over the semiconductor wafer and a connector that is physically secured and electronically coupled to the interconnect layer. In one or more embodiments, the connector is physically secured and electronically coupled to the interconnect layer by a structure comprising an bond layer and an electrically conductive layer. In one or more embodiments, the structure is formed according to a methodology that includes forming a bond layer over the interconnect layer, forming the electrically conductive layer as a solder layer over the bond layer, and applying a reflow operation to at least the solder layer.

### GOVERNMENT LICENSE RIGHTS

The invention described in the present disclosure was made with government support under government contract number H98230-13-D-0173 awarded by the National Security Agency. The government has certain rights in the invention.

### BACKGROUND

The present disclosure relates in general to coupling electronic signals into and out of an integrated circuit (IC). More specifically, the present disclosure relates to systems, methodologies and resulting structures for executing the direct transfer of electronic signals into and out of a semiconductor-based IC in a manner that eliminates the need for intermediary coupling mechanisms such as printed circuit boards (PCBs), wire bond connections, and the like.

Semiconductor devices are used in a variety of electronic and electro-optical applications. ICs are typically formed from various circuit configurations of semiconductor devices formed on semiconductor wafers. Alternatively, semiconductor devices may be formed as monolithic devices, e.g., discrete devices. Semiconductor devices are formed on semiconductor wafers by depositing many types of thin films of material over the semiconductor wafers, patterning the thin films, doping selective regions of the semiconductor wafers, etc. In a conventional semiconductor fabrication process, a large number of semiconductor devices are fabricated in a single wafer. CMOS (complementary metal-oxide semiconductor) is the semiconductor fabrication technology used in the transistors that are manufactured into most of today's computer microchips. In CMOS technology, both n-type and p-type transistors are used in a complementary way to form a current gate that forms an effective means of electrical control. Processing steps performed later in CMOS technology fabrication sequences are referred to as back-end-of-line (BEOL) CMOS processing, and processing steps performed earlier in CMOS technology fabrication sequences are referred to as front-end-of-line (FEOL) CMOS processing.

After completion of device level and interconnect level fabrication processes, the semiconductor devices on the wafer are separated into micro-chips (i.e., chips), and the final product is packaged. IC packaging typically involves encasing the silicon chip(s) inside a hermetically sealed plastic, metal or ceramic package that prevents the chip(s) from being damaged by exposure to dust, moisture or contact with other objects. IC packaging also allows easier connections to a PCB. The purpose of a PCB is to connect ICs and discreet components together to form larger operational circuits. Other parts that can be mounted to the PCB include card sockets, microwave connectors, and the like.

Wire bonding is a known BEOL operation for forming electrical interconnections between a PCB and other components (e.g., external components, card sockets, microwave connectors, etc.). In wire bonding, a length of small diameter soft metal wire (e.g., gold (Au), copper (Cu), silver (Ag), aluminum (Al), and the like) is attached or bonded without the use of solder to a compatible metallic surface or pad mounted on a PCB. The actual bond between the wire and the pad can be formed in a variety of ways, including thermocompression, thermosonic and ultrasonic. Although wire bonding is widely used, the additional wire bond hardware, particularly in microwave/radio frequency (RF) applications, is manually intensive to fabricate, suffers from low temperature CTE (coefficient of thermal expansion) mismatches, is difficult to reliably repeat, causes signal path problems, increases cost, adds bulk and introduces extraneous microwave cavity modes.

### SUMMARY

Embodiments are directed to a method of forming a coupler system. The method includes forming a semiconductor wafer, forming an interconnect layer coupled to the semiconductor wafer, and physically securing and electronically coupling a connector to the interconnect layer.

Embodiments are further directed to a method of forming a coupler system. The method includes forming a semiconductor wafer, forming an interconnect layer coupled to the semiconductor wafer, forming radio frequency (RF) circuitry electronically coupled to the interconnect layer, physically securing and electronically coupling a microwave connector to the interconnect layer.

Embodiments are further directed to a method of forming a coupler system. The method includes forming a semiconductor wafer, forming an interconnect layer coupled to the semiconductor wafer, forming radio frequency (RF) circuitry electronically coupled to the interconnect layer, physically securing and electronically coupling a microwave connector to the interconnect layer, wherein the microwave connector and interconnect layer are configured to couple electronic signals to the RF circuitry.

Embodiments are further directed to a coupler system including a semiconductor wafer, an interconnect layer coupled to the semiconductor wafer and a connector formed over the interconnect layer, wherein the connector is physically secured and electronically coupled to the interconnect layer. In one or more of the above-described embodiments, the connector is physically secured and electronically coupled to the interconnect layer by a structure comprising a bond layer and an electrically conductive layer. In one or more of the above-described embodiments, the structure is formed according to a methodology that includes forming the bond layer over the interconnect layer, forming the electrically conductive layer as a solder layer over the bond layer, and applying a reflow operation to at least the solder layer.

Embodiments are further directed to a coupler system including a semiconductor wafer, an interconnect layer coupled to the semiconductor wafer, and RF circuitry electronically coupled to the interconnect layer. The coupler system further includes a microwave connector physically secured and electronically coupled to the interconnect layer. In one or more of the above-described embodiments, the microwave connector is physically secured and electronically coupled to the interconnect layer by a structure. In one or more of the above-described embodiments, the structure comprises a bond layer and an electrically conductive layer. In one or more of the above-described embodiments, the structure is formed according to a methodology that includes forming the bond layer over the interconnect layer, forming the electrically conductive layer as a solder layer over the bond layer, and applying a reflow operation to at least the solder layer.

Additional features and advantages are realized through the techniques described herein. Other embodiments and aspects are described in detail herein. For a better understanding, refer to the description and to the drawings.

### BRIEF DESCRIPTION OF THE DRAWINGS

The subject matter which is regarded as the present disclosure is particularly pointed out and distinctly claimed in the claims at the conclusion of the specification. The foregoing and other features and advantages are apparent from the following detailed description taken in conjunction with the accompanying drawings in which:

FIG. 1A depicts a cross-sectional view of a semiconductor wafer after an initial fabrication stage according to one or more embodiments;

FIG. 1B depicts a top-down view of a connector pattern of an exemplary microwave connector according to one or more embodiments;

FIG. 2A depicts a cross-sectional view of a semiconductor wafer after a fabrication stage according to one or more embodiments;

FIG. 2B depicts a top-down view of the semiconductor wafer shown in FIG. 2A;

FIG. 3A depicts a cross-sectional view of a semiconductor wafer after a fabrication stage according to one or more embodiments;

FIG. 3B depicts a top-down view of the semiconductor wafer shown in FIG. 3A;

FIG. 4A depicts a cross-sectional view of a semiconductor wafer after a fabrication stage according to one or more embodiments;

FIG. 4B depicts a top-down view of the semiconductor wafer shown in FIG. 4A; and

FIG. 5 depicts a flow diagram illustrating a fabrication methodology according to one or more embodiments.

In the accompanying figures and following detailed description of the disclosed embodiments, the various elements illustrated in the figures are provided with three or four digit reference numbers. The leftmost digit(s) of each reference number corresponds to the figure in which its element is first illustrated.

### DETAILED DESCRIPTION

It is understood in advance that, although this disclosure includes a detailed description of attaching a specific type of microwave connector to interconnect metallurgy on a silicon wafer/chip, implementation of the teachings recited herein are not limited to a particular type of connector or transmission architecture. Rather embodiments of the present disclosure are capable of being implemented in conjunction with any other type of connector or transmission architecture, now known or later developed.

Various embodiments of the present disclosure are described herein with reference to the related drawings. Alternative embodiments may be devised without departing from the scope of this disclosure. It is noted that various connections and positional relationships (e.g., over, below, adjacent, etc.) are set forth between elements in the following description and in the drawings. These connections and/or positional relationships, unless specified otherwise, may be direct or indirect, and the present disclosure is not intended to be limiting in this respect. Accordingly, a coupling of entities may refer to either a direct or an indirect coupling, and a positional relationship between entities may be a direct or indirect positional relationship. As an example of an indirect positional relationship, references in the present disclosure to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The term “exemplary” is used herein to mean “serving as an example, instance, or illustration.” Any embodiment or design described herein as “exemplary” is not necessarily to be construed as preferred or advantageous over other embodiments or designs. The terms “at least one” and “one or more” may be understood to include any integer number greater than or equal to one, i.e. one, two, three, four, etc. The terms “a plurality” may be understood to include any integer number greater than or equal to two, i.e. two, three, four, five, etc. The term “connection” may include both an indirect “connection” and a direct “connection.”

As previously noted herein, after completion of device level and interconnect level fabrication processes, the semiconductor devices on the wafer are separated into micro-chips (i.e., chips), and the final products is packaged. IC packaging typically involves encasing the silicon chip(s) inside a hermetically sealed plastic, metal or ceramic package that prevents the chip(s) from being damaged by exposure to dust, moisture or contact with other objects. IC packaging also allows easier connections to a PCB. The purpose of a PCB is to connect ICs and discreet components together to form larger operational circuits. Other parts that can be mounted to the PCB include card sockets, microwave connectors, and the like.

Wire bonding is a known BEOL operation for forming electrical interconnections between a PCB and other components (e.g., external components, card sockets, microwave connectors, etc.). In wire bonding, a length of small diameter soft metal wire (e.g., Au, Cu, Ag, Al, and the like) is attached or bonded with the use of solder to a compatible metallic surface or pad mounted on a PCB. The actual bond between the wire and the pad can be formed in a variety of ways, including thermocompression, thermosonic and ultrasonic. Although wire bonding is widely used, the additional wire bond hardware, particularly in microwave/RF applications, is manually intensive to fabricate, suffers from low temperature CTE mismatches, is difficult to reliably repeat, causes signal path problems, increases cost, adds bulk and introduces extraneous microwave cavity modes.

The present disclosure provides systems, methodologies and resulting structures for executing the direct transfer of electronic signals into and out of a semiconductor-based IC in a manner that eliminates the need for intermediary coupling mechanisms such as PCBs, wire bond connections, and the like. In one or more embodiments, electronic connectors (e.g., microwave connectors) are attached directly to interconnect metallurgy (e.g., Cu, Al, etc.) on a semiconductor (e.g., Si, GaAs, and the like) wafer or chip. The interconnect metallurgy (or interconnect layer) can take a variety of forms, including, for example, metal on film, damascene metal, diffusion or any other type of conductive contact area on the wafer. In one or more embodiments, a bond stack and solder attachment method is utilized to physically secure and electronically couple the electronic connectors directly to the interconnect metallurgy layer. The bond stack metallurgy is tailored to the specific joining method and material. In one or more embodiments, the disclosed semiconductor wafer functions as an interposer that couples the electronic connector to other circuitry (e.g., RF circuitry) on the semiconductor wafer. Accordingly, the present disclosure avoids the manually intensive fabrication, low temperature CTE mismatches, lack of repeatability, signal path problems, increased cost, added bulk and extraneous microwave cavity modes introduced by routing electronic signals through intermediary coupling mechanisms such as PCBs and wire bond connections.

For the sake of brevity, conventional techniques related to semiconductor device and IC fabrication may not be described in detail herein. Moreover, the various tasks and process steps described herein may be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

By way of background, however, a more general description of the semiconductor device fabrication processes that may be utilized in implementing one or more embodiments of the present disclosure will now be provided. Although specific fabrication operations used in implementing one or more embodiments of the present disclosure may be individually known, the disclosed combination of operations and/or resulting structures of the present disclosure are unique. Thus, the unique combination of the operations described in connection with the fabrication of a coupler system according to the present disclosure utilize a variety of individually known physical and chemical processes performed on a semiconductor (e.g., silicon) substrate. In general, the various processes used to form a micro-chip that will be packaged into an IC fall into three categories, namely, film deposition, patterning, etching and semiconductor doping. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

Fundamental to all of the above-described fabrication processes is semiconductor lithography, i.e., the formation of three-dimensional relief images or patterns on the semiconductor substrate for subsequent transfer of the pattern to the substrate. In semiconductor lithography, the patterns are a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

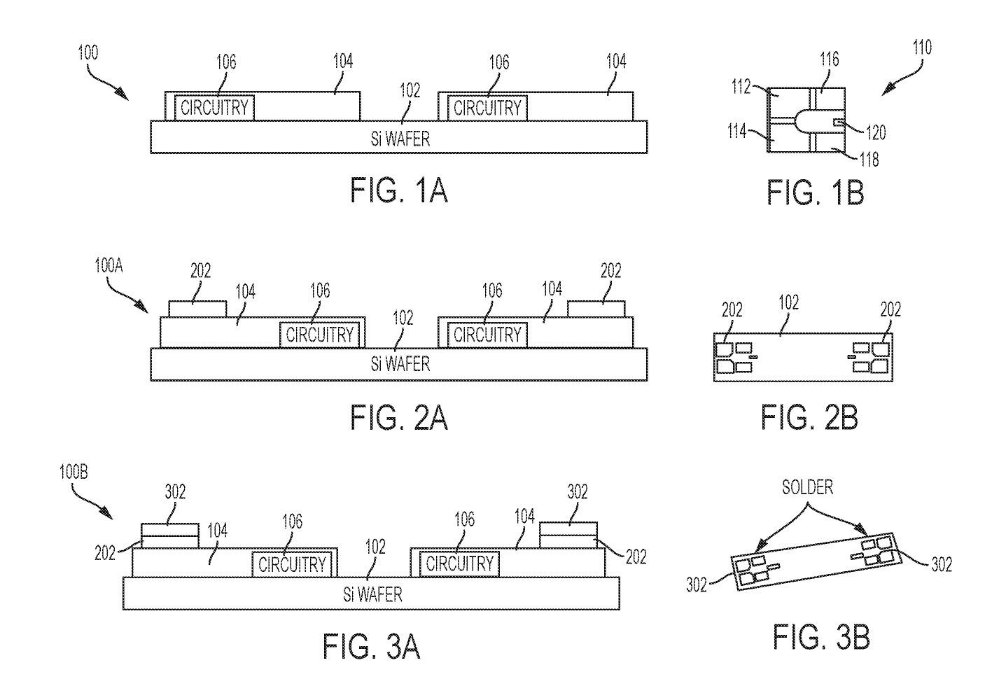

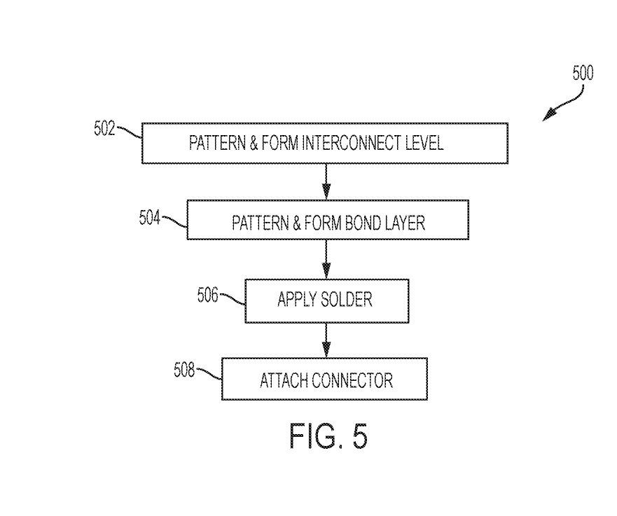

Turning now to a more detailed description of one or more embodiments, a fabrication methodology for forming various stages of a coupler system according to the present disclosure will now be described with reference to FIGS. 1A-5. More specifically, FIGS. 1A-4B illustrate coupler system structures 100, 100A, 100B, 100C after various fabrication stages, and FIG. 5 depicts the operations of a fabrication methodology 500 that correspond to the fabrication stages shown in FIGS. 1A-4B. The following description will refer simultaneously to both the fabrication stages depicted in FIGS. 1A-4B and the corresponding operation(s) of methodology 500 depicted in FIG. 5. It is noted that coupler systems 100, 100A, 100B, 100C shown in FIGS. 1A-4B are greatly simplified for ease of illustration and description. In practice, a coupler system embodying the present disclosure may include multiple configurations of electronic connectors, RF circuitry, interconnect layers, bond layers and solder layers.

FIG. 1A depicts a cross-sectional view of coupler system 100 after an initial fabrication stage (block 502) according to one or more embodiments. Coupler system 100 includes an interconnect layer 104 formed using conventional semiconductor fabrication techniques (e.g., patterning, etc.) over a semiconductor (e.g., silicon) wafer 102, which is also formed using conventional semiconductor fabrication techniques (e.g., epitaxial growth, etc.). Circuitry 106 (e.g., RF circuitry) may be formed in a variety of ways. For example, the formation of circuitry 106 may be incorporated, using known fabrication techniques, with the fabrication processes for forming interconnect layer 104 and/or silicon wafer 102. Alternatively, circuitry 106 may be formed separately from and electrically coupled to interconnect layer 104. In the embodiments shown in the FIGS., the formation of circuitry 106 is incorporated using known fabrication techniques with the fabrication processes for forming interconnect layer 104. In general, interconnects such as interconnect layer 104 serve as the streets and highways of the IC that will ultimately be formed from coupler system 100, thereby connecting elements (e.g., circuitry 106) of the IC into a functioning whole and to the outside world. Interconnect levels (or metal layers) vary in numbers depending on the complexity of the device.

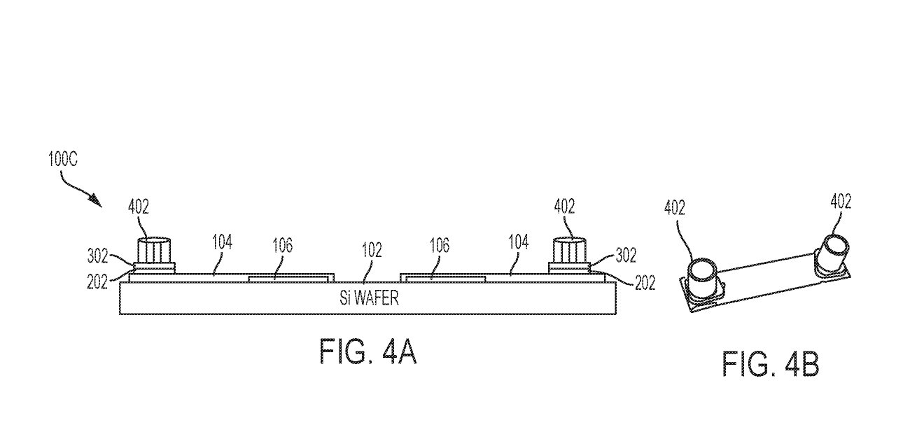

FIG. 1B depicts a connector pattern 110 that matches the five (5) electrical connections of an exemplary surface-mount microwave connector 402 (shown in FIGS. 4A and 4B) according to one or more embodiments. In one or more embodiments, surface-mount microwave connector 402 is implemented as a surface-mount microwave connector commercially available under the tradename “SMP.” The five (5) electrical connections outlined by connector pattern 110 include four (4) ground pads 112, 114, 116, 118 and one (1) signal pad 120 that match the ground pads and signal pad formed on the bottom of microwave connector 402. For an SMP connector, the area occupied by the ground pads and signal pad is approximately 2 millimeters by 2 millimeters. The illustrated connector pattern 110 and surface-mount microwave connector 402 are exemplary, and virtually any connector pattern and/or type of connector may be utilized in connection with the present disclosure.

FIG. 2A depicts a cross-sectional view of a coupler system 100A after a subsequent fabrication stage (block 504) according to one or more embodiments. In coupler system 100A, a bond layer 202 is formed using conventional semiconductor device fabrication techniques (e.g., patterning, etc.) to match connector pattern 110 (shown in FIG. 1B). After formation of bond layer 202, a bond layer stack is present over silicon wafer 102 consisting of a portion of interconnect layer 104 and bond layer 202. FIG. 2B depicts a top-down view of coupler system 100A shown in FIG. 2A.

FIG. 3A depicts a cross-sectional view of a coupler system 100B after another subsequent fabrication stage (block 506) according to one or more embodiments. In coupler system 100B, an electrically conductive layer in the form of a solder layer (e.g., Indium (In)/In-alloys and flux) 302 is formed using conventional semiconductor device fabrication techniques (e.g., patterning, etc.) to match connector pattern 110 (shown in FIG. 1B). After formation of solder layer 302, a bond/solder layer stack is present over silicon wafer 102 consisting of a portion of interconnect layer 104, bond layer 202 and solder layer 302. FIG. 3B depicts a top-down view of coupler system 100B shown in FIG. 3A.

FIG. 4A depicts a cross-sectional view of a coupler system 100C after another subsequent fabrication stage (block 508) according to one or more embodiments. In coupler system 100C, microwave connector 402 is positioned over a structure formed by the bond/solder layer stack (i.e., a portion of interconnect layer 104, bond layer 202 and solder layer 302) such that the five (5) electrical connections of microwave connector 402 (e.g., connector pattern 110 shown in FIG. 1B) are over the matching portions of solder layer 302 and bond layer 202. A reflow process is applied to the bond/solder layer stack. In an exemplary reflow process, coupler assembly 100C is subjected to controlled heat, which melts at least solder layer 302, thereby attaching microwave connector 402 through the bond/solder layer stack to silicon wafer 102, and providing electronic coupling between and among microwave connector 402, solder layer 302, bond layer 202, interconnect layer 104 and any components and/or circuitry (e.g., circuitry 106) coupled to interconnect layer 104 over silicon wafer 102. In one or more embodiments, solder layer 302 after reflow provides a permanent attachment of microwave connector 402. Heating may be accomplished by passing coupler system 100C through a reflow oven or under an infrared lamp or by soldering the bond/solder layer stack with a hot air pencil. The reflow process melts at least solder layer 302 and heats the adjoining surfaces without overheating and damaging the electrical components. An exemplary reflow process includes four stages or zones, namely preheat, thermal soak, reflow and cooling, wherein each stage has a distinct thermal profile. An exemplary reflow process is conducted in an acid environment using, for example, formic acid). The acid environment ensures that the solder remains clean during reflow. After the reflow process is complete, microwave connector 402 is physically attached and electronically coupled through the bond/solder stack (i.e., solder layer 302, bond layer 202 and a portion of interconnect layer 104) to silicon wafer 102, thereby providing physical coupling between microwave connector 402 and wafer 102, as well as electronic coupling between microwave connector 402 and circuitry 106. The post-reflow solder layer 302 is compliant, particularly when the solder layer 302 is In, which mitigates the impact of CTE mismatches. FIG. 4B depicts a top-down view of coupler system 100C shown in FIG. 4A.

Thus, it can be seen from the foregoing detailed description and accompanying illustrations that one or more embodiments of the present disclosure provide systems, methodologies and resulting structures for executing the direct transfer of electronic signals into and out of a semiconductor-based IC in a manner that eliminates the need for intermediary coupling mechanisms such as PCBs, wire bond connections, and the like. In one or more embodiments, electronic connectors (e.g., microwave connectors) are attached directly to interconnect metallurgy (e.g., Cu, Al, etc.) on a semiconductor (e.g., Si, GaAs, and the like) wafer or chip. In one or more embodiments, a bond stack and solder attachment method is utilized to physically secure and electronically couple the electronic connectors directly to the interconnect metallurgy layer. Eliminating the need for intermediary coupling mechanisms such as PCBs, wire bond connections, and the like, minimizes the use of non-like materials in the structure that physically couples microwave connector 402 to wafer 102, which mitigates the impact of low temperature CTE mismatches. Additionally, the relatively small size (e.g., 2 millimeters by 2 millimeters) area of the microwave connector 402 that is coupled through the bond stack to the wafer 102 further mitigates the impact of low temperature CTE mismatches. The bond stack metallurgy is tailored to the specific joining method and material. In one or more embodiments, the disclosed semiconductor wafer functions as an interposer that couples the electronic connector to other circuitry (e.g., RF circuitry, microwave circuitry, transmissions lines, resonators, capacitors, etc.) on the semiconductor wafer. Accordingly, the present disclosure avoids the manually intensive fabrication, low temperature CTE mismatches, lack of repeatability, signal path problems, increased cost, added bulk and extraneous microwave cavity modes introduced by routing electronic signals through intermediary coupling mechanisms such as PCBs and wire bond connections.

In some embodiments, various functions or acts may take place at a given location and/or in connection with the operation of one or more apparatuses or systems. In some embodiments, a portion of a given function or act may be performed at a first device or location, and the remainder of the function or act may be performed at one or more additional devices or locations.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description, but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The flowchart and block diagrams in the figures illustrate the functionality and operation of possible implementations of systems and methods according to various embodiments of the present disclosure. In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. The actions may be performed in a differing order or actions may be added, deleted or modified. Also, the term “coupled” describes having a signal path between two elements and does not imply a direct connection between the elements with no intervening elements/connections therebetween. All of these variations are considered a part of the disclosure.

The term “about” is intended to include the degree of error associated with measurement of the particular quantity based upon the equipment available at the time of filing the application. For example, “about” can include a range of ±8% or 5%, or 2% of a given value.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

While the present disclosure has been described in detail in connection with only a limited number of embodiments, it should be readily understood that the present disclosure is not limited to such disclosed embodiments. Rather, the present disclosure can be modified to incorporate any number of variations, alterations, substitutions or equivalent arrangements not heretofore described, but which are commensurate with the spirit and scope of the present disclosure. Additionally, while various embodiments of the present disclosure have been described, it is to be understood that aspects of the present disclosure may include only some of the described embodiments. Accordingly, the present disclosure is not to be seen as limited by the foregoing description, but is only limited by the scope of the appended claims.

1. A method of forming a coupler system, the method comprising:
forming a semiconductor wafer;
forming an interconnect layer over the semiconductor wafer;
physically securing a mounting surface of a connector to the interconnect layer;
wherein the mounting surface comprises a signal pad;
wherein the connector further comprises a coupling mechanism configured to couple the connector to a cable; and
electronically coupling the connector to the interconnect layer through the signal pad.

2. The method of claim 1, wherein physically securing the connector to the interconnect layer comprises forming a bond layer over the interconnect layer.

3. The method of claim 2, wherein physically securing the connector to the interconnect layer comprises forming a solder layer over the bond layer.

4. The method of claim 3, wherein physically securing the connector to the interconnect layer comprises applying a reflow operation to at least the solder layer.

5. The method of claim 1, wherein electronically coupling the connector to the interconnect layer comprises forming a bond layer over the interconnect layer.

6. The method of claim 5, wherein electronically coupling the connector to the interconnect layer comprises forming a solder layer over the bond layer.

7. The method of claim 6, wherein electronically coupling the connector to the interconnect layer comprises applying a reflow operation to at least the solder layer.

8. A method of forming a coupler system, the method comprising:
forming a semiconductor wafer;
forming an interconnect layer over the semiconductor wafer;
forming radio frequency (RF) circuitry over the interconnect layer;
electronically coupling the RF circuitry to the interconnect layer;
physically securing a mounting surface of a microwave connector to the interconnect layer;
wherein the mounting surface comprises a signal pad;
wherein the connector further comprises a coupling mechanism configured to couple the microwave connector to a coaxial cable; and
electronically coupling the microwave connector to the interconnect layer through the signal pad.

9. The method of claim 8, wherein physically securing the microwave connector to the interconnect layer comprises forming a bond layer over the interconnect layer.

10. The method of claim 9, wherein physically securing the microwave connector to the interconnect layer comprises forming a solder layer over the bond layer.

11. The method of claim 10, wherein physically securing the microwave connector to the interconnect layer comprises applying a reflow operation to at least the solder layer.

12. The method of claim 8, wherein electronically coupling the microwave connector to the interconnect layer comprises forming a bond layer over the interconnect layer.

13. The method of claim 12, wherein electronically coupling the microwave connector to the interconnect layer comprises forming a solder layer over the bond layer.

14. The method of claim 13, wherein electronically coupling the microwave connector to the interconnect layer comprises applying a reflow operation to at least the solder layer.

15. A method of forming a coupler system, the method comprising:
forming a semiconductor wafer;
forming an interconnect layer over the semiconductor wafer;
forming radio frequency (RF) circuitry over the interconnect layer;
electronically coupling the RF circuitry to the interconnect layer;
physically securing a mounting surface of a microwave connector to the interconnect layer;
wherein the mounting surface comprises a signal pad;
wherein the connector further comprises a coupling mechanism configured to couple the microwave connector to a coaxial cable; and
electronically coupling the microwave connector to the interconnect layer through the signal pad;
wherein the microwave connector and interconnect layer are configured to couple electronic signals to the RF circuitry.

16. The method of claim 15, wherein physically securing the connector to the interconnect layer comprises forming a bond layer over the interconnect layer.

17. The method of claim 16, wherein physically securing the connector to the interconnect layer comprises forming a solder layer over the bond layer.

18. The method of claim 17, wherein physically securing the connector to the interconnect layer comprises applying a reflow operation to at least the solder layer.

19. The method of claim 15, wherein electronically coupling the connector to the interconnect layer comprises forming a bond layer over the interconnect layer.

20. The method of claim 19, wherein electronically coupling the connector to the interconnect layer comprises forming a solder layer over the bond layer.

21. The method of claim 20, wherein electronically coupling the connector to the interconnect layer comprises applying a reflow operation to at least the solder layer.

22. A coupler system comprising:
a semiconductor wafer;
an interconnect layer formed over the semiconductor wafer; and
a connector formed over the interconnect layer, wherein the connector is physically secured and electronically coupled to the interconnect layer, wherein the connector comprises a coupling mechanism configured to couple the connector to a cable.

23. The system of claim 22, wherein:
the connector is physically secured and electronically coupled to the interconnect layer by a structure comprising:
a bond layer over the interconnect layer; and
an electrically conductive layer coupled to the bond layer.

24. A coupler system comprising:
a semiconductor wafer;
an interconnect layer formed over the semiconductor wafer;
radio frequency (RF) circuitry electronically coupled to the interconnect layer; and
a microwave connector physically secured and electronically coupled to the interconnect layer, wherein the microwave connector comprises a coupling mechanism configured to couple the microwave connector to a coaxial cable.

25. The system of claim 24, wherein:
the microwave connector is physically secured and electronically coupled to the interconnect layer by a structure comprising:
a bond layer over the interconnect layer; and
an electrically conductive layer coupled to the bond layer.
